(19) United States
(12) Patent Application Publication
(10) Pub. No.: US 2025/0226280 A1
(43) Pub. Date: Jul. 10, 2025

(54) PACKAGE ASSEMBLY WITH BACK PLATE COMPRESSION

(71) Applicant: Taiwan Semiconductor Manufacturing Company, Ltd., Hsin-Chu (TW)

(72) Inventors: Wensen Hung, Hsinchu County (TW); Tsung-Yu Chen, Hsinchu City (TW)

(21) Appl. No.: 18/627,561

(22) Filed: Apr. 5, 2024

Related U.S. Application Data
(60) Provisional application No. 63/617,455, filed on Jan. 4, 2024.

(51) Int. Cl. H01L 23/367; H01L 23/00; H01L 23/40; H01L 23/42; H05K 1/02; H05K 1/18

(52) U.S. Cl. CPC H01L 23/367; H01L 23/4006; H01L 23/42; H01L 24/32; H05K 1/0203; H05K 1/181; H01L 2224/32225

(57) ABSTRACT

One aspect of the present disclosure pertains to an integrated circuit (IC) package assembly. The IC package assembly includes a printed circuit board (PCB); a packaged IC structure mounted on a top surface of the PCB; a heat sink structure disposed over the packaged IC structure; and a back plate secured on a bottom surface of the PCB. The back plate includes a base portion and a protruding portion. The protrusion portion protrudes from the base portion and a portion of the PCB is below the packaged IC structure. A lateral width of the protrusion portion is smaller than a lateral width of the base portion.

### PRIORITY DATA

This application claims the benefit of U.S. Provisional Application No. 63/617,455 filed Jan. 4, 2024, the entirety of which is herein incorporated.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Demands for more power and more condensed chip space (e.g., in high performance computing (HPC) and artificial intelligence (AI) applications) require proportional advancements in thermal management. For example, in HPC and AI applications, a critical issue is the hot spot thermal dissipation within CPUs and GPUs. The CPUs and GPUs may have a maximum power density up to 4 W/mm² surrounded by total chip power greater than about 400 W to about 600 W. However, current 3D IC package configurations may not achieve such thermal requirement. The heat dissipation efficiency in existing 3D IC packages require improvements in order to meet power demands of data centers running HPC and AI workloads.

Therefore, although existing 3D IC packages have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates an integrated circuit (IC) package assembly having a back plate configured to apply physical compression for improved thermal distribution, according to an embodiment of the present disclosure.

FIG. 2 illustrates an IC package assembly having a back plate (e.g., the IC package assembly of FIG. 1), where the back plate is secured to a heat sink structure, according to an embodiment of the present disclosure.

FIG. 3 illustrates the mechanism of enhanced heat transfer in an IC package assembly (e.g., the IC package assembly of FIG. 1), according to an embodiment of the present disclosure.

FIGS. 4A and 4B illustrate the mechanism of enhanced heat transfer using a leaf spring arm as part of a back plate of an IC package assembly, according to an embodiment of the present disclosure.

FIG. 5 illustrates an IC package assembly having a back plate with a protrusion pad, according to an embodiment of the present disclosure.

FIG. 6 illustrates an IC package assembly having a back plate with protrusion stubs, according to an embodiment of the present disclosure.

FIG. 7 illustrates an IC package assembly having a protrusion stub of irregular bump size, according to an embodiment of the present disclosure.

FIG. 8 illustrates an IC package assembly having a back plate with spring units, according to an embodiment of the present disclosure.

FIGS. 9A, 9B, 9C, and 9D illustrate back plates with various types of square and rectangular protrusion features, according to various embodiments of the present disclosure.

FIGS. 10A, 10B, 10C, and 10D illustrate back plates with various types of circular (in combination with square and rectangular) protrusion features, according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to integrated circuit (IC) package assemblies. The IC package assemblies may include stacked IC chips in a 3D IC package configuration. The stacked IC chips generate a certain amount of power that require adequate thermal management to sustain operations. The present disclosure describes IC package assemblies that include a back plate configured to apply physical compression upon a die (or IC chip) for improved heat distribution. In the present embodiments, each package assembly includes at least a die having functional devices such as logic and memory transistor devices, and the back plate applies a force to the die area. The applied force improves thermal contact of a thermal interface (TIM) layer over the die, thereby improving heat dissipation. Note that the back plate configuration described herein may be implemented in a standalone package assembly or as part of a 3D Fabric such as CoWoS/InFO/SoIC with multiple dies stacking in 2.5D and/or 3D IC configurations.

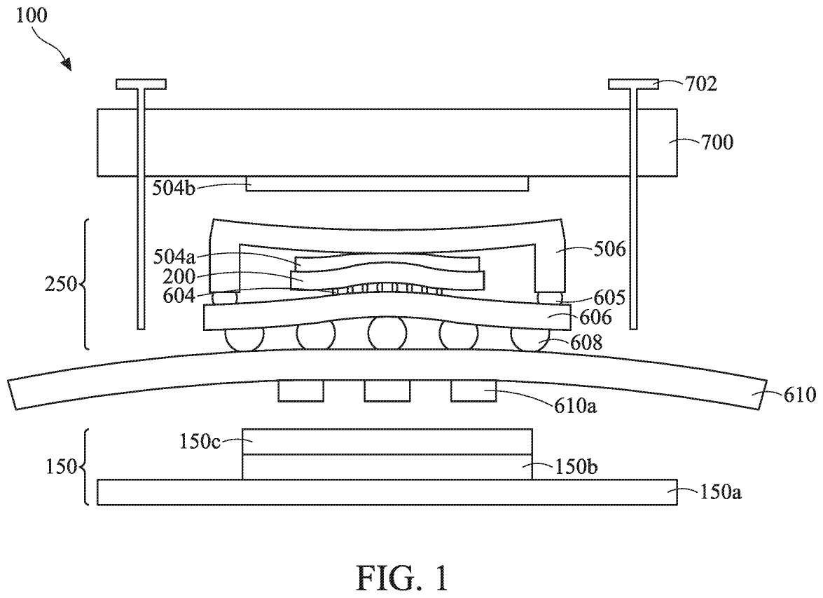

FIG. 1 illustrates an integrated circuit (IC) package assembly 100 having a back plate 150 configured to apply physical compression for improved thermal distribution. The IC package assembly 100 includes a packaged IC structure 250 (or IC package 250) mounted on a top surface of a printed circuit board (PCB) 610. The IC package assembly 100 includes a heat sink structure 700 disposed over the packaged IC structure 250. The IC package assembly 100 includes a back plate 150 disposed below a bottom surface of the PCB 610.

Still referring to FIG. 1, the packaged IC structure 250 includes at least a die 200 with various active and passive devices (e.g., transistor devices, resistors, capacitors, carrier substrate, etc.) formed thereon. Although only one die 200 is shown, note that the packaged IC structure 250 may include more than one die 200. In an embodiment, the packaged IC structure 250 may include multiple dies 200 disposed adjacent to each other in the lateral direction. In another embodiment, the packaged IC structure 250 may include multiple dies 200 stacked on top of each other in the vertical direction. In yet another embodiment, the packaged IC structure 250 may include dies 200 disposed adjacent each other and dies 200 stacked on top of each other to form various integrated 3DIC stacked structures. Each of the dies 200 may include a device layer sandwiched between various IC layers and components (e.g., sandwiched between a frontside interconnect structure and a backside interconnect structure). The device layer is where device-level features such as transistor devices are formed. The transistor devices may be logic devices, memory devices, or the like. Each of the transistor devices includes a channel region between source/drain (S/D) regions and a gate stack over the channel regions. The device layer may further include other device-level features such as S/D contacts, S/D vias, gate contacts, and/or gate vias, each of which may electrically connect the S/D regions and/or the gate stacks to a higher or lower material layer of the die 200 (e.g., frontside and/or backside interconnect structures). The die 200 may include a frontside interconnect structure over the device layer and a backside interconnect structure under the device layer. The frontside and backside interconnect structures may include metal lines and vias embedded in intermetal dielectric (IMD) layers, and the metal lines and vias route signals to and from the transistor devices in the device layer. In an embodiment, as part of (or separate from) the die 200, a bonding layer is disposed over the frontside interconnect structure, and a carrier substrate is disposed over the bonding layer. For example, the bonding layer and the carrier substrate (e.g., made of silicon) are formed to provide structural support when forming the backside interconnect structure.

Still referring to FIG. 1, the packaged IC structure 250 further includes a thermal interface material (TIM) layer 504a disposed on a top surface of the die 200. In embodiments where there are multiple stacked dies 200, the TIM layer 504a is disposed on a top surface of the topmost die 200. The TIM layer 504a may be disposed on a top surface of a frontside interconnect structure of the die 200 or a carrier substrate of the die 200. The TIM layer 504a may act as a heat conductor and heat distributor on a front side of the die 200 to more uniformly direct heat away from the die 200. The TIM layer 504a may also act as a protective film to keep out moisture from outside the packaged IC structure 250. The TIM layer 504a may also act as an adhesive film to bond between the die 200 and the lid 506. The TIM layer 504a may include a polymer, resin, or epoxy as a base material, and a filler to improve its thermal conductivity. The filler may include a dielectric filler such as aluminum oxide, magnesium oxide, aluminum nitride, boron nitride, and diamond powder. Alternatively, the filler may include a metal filler such as silver, copper, aluminum, or the like.

Still referring to FIG. 1, the packaged IC structure 250 further includes a lid 506 disposed on a top surface of the TIM layer 504a. The lid 506 may be a metal cap that acts as a cover for the packaged IC structure. In an embodiment, the lid not only covers a top surface of the die, but also cover side surfaces of the TIM layer 504a, the die 200, and a C4 layer having interconnect bumps 604 (see description below). Besides acting as a cover, the lid 506 also acts as a heat absorber to absorb any heat dissipated from components of the die 200. The lid 506 absorbs heat from the die 200 through the TIM layer 504a. The lid 506 is formed of a metal or a metal alloy, which has a high thermal conductivity, for example, higher than about 100 W/m/K. For example, the lid may be formed of a metal, or a metal alloy selected from Al, Cu, Ni, Co, stainless steel, and alloys thereof. The lid 506 may be mounted onto a package substrate 606 through base adhesive joints 605. The base adhesive joints 605 may include glue the lid 506 onto the package substrate 606. The base adhesive joints 605 be made of any suitable material (e.g., epoxy, adhesive tapes, etc.).

Still referring to FIG. 1, the packaged IC structure 250 further includes a controlled collapse chip connection (C4) layer under the die 200. The C4 layer includes interconnect bumps 604 such as solder bumps or copper pillar (CuP) bumps. The solder bumps may include tin, lead, and/or silver, and the CuP bumps may include a copper pillar having a solder cap at the end. The solder cap may be made of tin, lead, and/or silver. The interconnect bumps 604 act as means for connecting a chip/die to another chip/die as part of an IC package 250, or to a package substrate 606 as part of an IC package 250. In an embodiment, the C4 layer is disposed on a back surface of a backside interconnect structure of the die 200. For example, the interconnect bumps 604 are disposed on aluminum bonding pads of the backside interconnect structure. The aluminum landing pads may be part of an aluminum pad layer. And the aluminum pad layer may be part of a redistribution layer (RDL) structure. The RDL structure may include redistribution routing lines embedded in one or more passivation layers. The redistribution routing lines may route the metal lines of the backside interconnect structure to the aluminum bonding pads of the aluminum bonding pad layer.

Still referring to FIG. 1, the packaged IC structure 250 further includes a package substrate 606 under the C4 layer. The package substrate 606 is disposed on a back side of the C4 layer. Or more specifically, the interconnect bumps 604 of the C4 layer land on landing pads of the package substrate 606. The package substrate 606 generally refers to a wafer or semiconductor structure that includes package components such as other device chips, silicon interposers, dielectric substrates, and the like. The package components are electrically connected to the die 200 through the interconnect bumps 604 of the C4 layer. In an embodiment, the package substrate 606 includes a semiconductor substrate formed of silicon, silicon germanium, silicon carbon, or the like.

Still referring to FIG. 1, the packaged IC structure 250 further includes a ball-grid array (BGA) structure under the package substrate 606. The BGA structure may include solder joints 608 that land on the PCB 610. As shown, the solder joints 608 are attached to the backside of the package substrate 606. The BGA structure is configured to bond one or more packaged IC structures 250 onto a larger circuit board (e.g., PCB 610). For example, the PCB 610 may include multiple other packaged IC structures 250 mounted thereon, thereby forming a processor, a controller, a memory unit, or other electronic components. The PCB 610 may further include surface mount (SMT) components 610a mounted on a back surface of the PCB 610. The SMT components 610a may also be referred to as surface-mount devices (SMDs). The SMT components 610a may include SMD capacitors, SMD inductors, PCB transformers, diodes, triodes, network resistors, oscillators, or other ICs (e.g., other packaged IC structures 250). Note that the PCB 610 and the package substrate 606 may be collectively referred to as a carrier base where the die 200 is mounted on. This carrier base may also be generally referred to as a package substrate, a base substrate, a substrate underlayer, or the like. The package substrate 606 and the PCB 610 may individually or collectively further include a laminate carrier, a metal lead frame, a ceramic substrate, or other types of substrates.

Still referring to FIG. 1, the back plate 150 and the heat sink structure 700 vertically sandwich the packaged IC structure 250 and the PCB 610. The heat sink structure 700 is disposed over the lid 506 of the packaged IC structure 250. In an embodiment, the IC package assembly 100 further includes a TIM layer 504b disposed on a top surface of the lid 506 and a bottom surface of the heat sink structure 700. The TIM layer 504b provides further heat distribution and adhesive functions between the lid 506 and the heat sink structure 700. The TIM layer 504b may include similar materials as the TIM layer 504a. In the embodiment shown, the TIM layer 504b may have a greater width in the lateral direction than the TIM layer 504a. For example, the TIM layer 504a extends a width of the die 200, the TIM layer 504b extends a width of the lid 506, and the width of the lid is greater than the width of the die 200. Since the TIM layer 504b is wider than the TIM layer 504a, there may be less thermal contact concerns in the TIM layer 504b than in the TIM layer 504a. Further, the TIM layer 504a is closer to the die 200 and has a greater impact on heat dissipation than the TIM layer 504b.

Still referring to FIG. 1, the back plate 150 is disposed below the PCB 610 and includes a base portion 150a and a protrusion portion 150b. In the embodiment shown, the back plate 150 further includes an elastomer pad 150c coterminous with a top surface of the protrusion portion 150b. The elastomer pad 150c may be referred to as a separate portion from the protrusion portion 150b or as part of the protrusion portion 150b. In some embodiments, the elastomer pad 150c is omitted. The base portion 150a and the protrusion portion 150b may include same materials, and the base portion has a greater width (and/or length) than the protrusion portion 150b. For example, the base portion 150a and the protrusion portion 150b both include a metal or a metal alloy. In an embodiment, the metal or metal alloy includes Al, Cu, Ni, Co, stainless steel, or combinations thereof. The protrusion portion 150b is configured to press against the backside of the PCB 610 (e.g., against SMT components 610a of the PCB 610). In the embodiment shown, the back plate 150 is configured to be in direct mechanical contact with the back side of the PCB 610 via an elastomer pad 150c. The elastomer pad 150c acts as a cushion directly touching the backside of the PCB 610 (SMT components 610a of the PCB 610). The elastomer pad 150c is pushed and compressed by the protrusion portion 150b. The elastomer pad 150c may include any rubbery material composed of long chainlike molecules, or polymers. In the present embodiments, the elastomer pad 150c may include natural rubbers, styrene-butadiene block copolymers, polyisoprene, polybutadiene, ethylene propylene rubber, ethylene propylene diene rubber, silicone elastomers, fluoroelastomers, polyurethane elastomers, or nitrile rubbers.

The IC package assembly 100 further includes fasteners 702 configured to secure the heat sink structure 700 to the back plate 150, or specifically to the base portion 150a of the back plate 150. The fasteners 702 may be screws, bolts, or other types of securement features. FIG. 1 illustrates the IC package assembly 100 before the fasteners 702 are secured onto the back plate 150. During device operation, if the fasteners 702 are not secured onto the back plate 150 (i.e., the protrusion portion 150b does not compress against the PCB 610), undesired warping may occur. For example, without compression, the die 200 generates heat, and the heat may cause the die 200 to warp downward (as shown), the lid 506 to warp upwards (as shown), and the package substrate 606 and the PCB 610 to warp warp downward (as shown). Due to such warping, the TIM layer 504a between the die 200 and the lid 506 may delaminate thereby causing voids and defects. Such delamination increases thermal resistance due to worsened thermal contact between the die 200 and the lid 506. Although such warping may also affect the TIM layer 504b, as described above, the TIM layer 504a is closer to the die 200 and has a greater impact on heat dissipation than TIM layer 504b. Further, TIM layer 504b is larger and has greater thermal surface contact area than the TIM layer 504a.

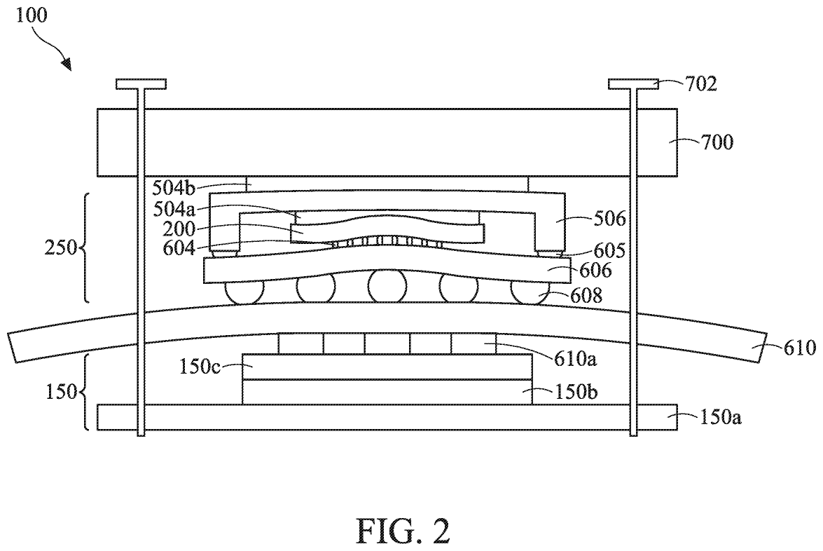

FIG. 2 illustrates an IC package assembly 100 having a back plate 150. FIG. 2 resembles FIG. 1, and the similar features will not be described again for the sake of brevity. The difference from FIG. 1 is that the back plate 150 is now secured to the heat sink structure 700. In other words, the fasteners 702 are secured onto the back plate 150 such that the protrusion portion 150b compresses against a back side of the PCB 610. As shown, the protrusion portion 150b (or elastomer pad 150c when present) may compress against SMT components 610a of the PCB 610. Due to the compression, the warping of the die 200 and the lid 506 is avoided. The compression to the PCB 610 transfers a force to a projected area of the die 200, and the force squeezes the die 200 against the lid 506 such that the TIM layer 504a is substantially free of air gaps and delamination, thereby improving thermal contact. As shown, the fasteners 702 may penetrate through the heat sink structure 700 and the PCB 610. The fasteners 702 are bolted down onto the base portion 150a of the back plate 150.

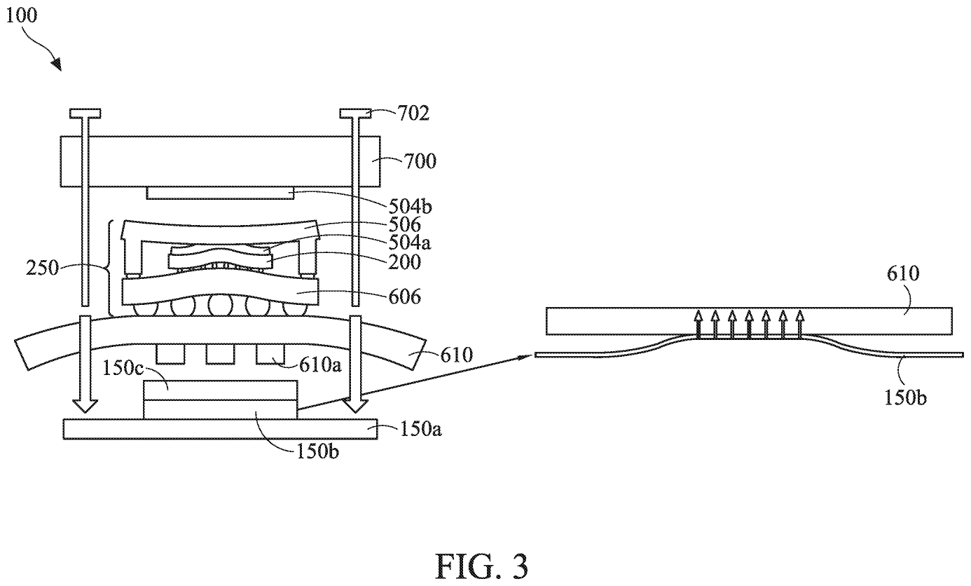

FIG. 3 illustrates the mechanism of enhanced heat transfer in an IC package assembly 100 (e.g., the IC package assembly 100 described in FIGS. 1-2). Referring to the left figure of FIG. 3, fasteners 702 are to be secured and bolted down onto the base portion 150a of the back plate 150. As such, a mechanical pressure is applied onto the packaged IC structure 250 and the heat sink structure 700 squeezes down onto the packaged IC structure 250. Such mechanical pressure is demonstrated by the downward arrows indicating where the fasteners 702 are to be bolted. To facilitate adequate compression for thermal improvements, the applied mechanical pressure is equal to about 10 to 50 PSI or a force of about 30 to 100 kg. If the pressure is too small, there is insufficient force to prevent warping. If the pressure is too big, the die 200 may be damaged. As described herein, the protrusion portion 150b is configured to generate a pre-pressure force onto a back side of the PCB 610. Due to the applied mechanical pressure, the pre-pressure force is transferred to a projected area of the die 200. To make sure force is applied to the projected area of the die 200, the protrusion portion 150b presses against a portion of the PCB 610 directly below the packaged IC structure 250. In other words, the protrusion portion 150b (or at least a portion thereof) is directly below the die 200. In an embodiment, the protrusion portion 150b vertically overlaps an entire width of the die 200 (as shown). Due to the compression force applied to the die 200, thermal contact is improved to promote efficient heat transfer from the packaged IC structure 250 to the system heat sink structure 700 (see arrow going upwards). The heat sink structure 700 may include cooling fans or cooling plates. The heat sink structure 700 is in thermal contact with the lid 506 (either by directly contacting the lid 506 or by indirectly contacting the lid 506 via the TIM layer 504b). As such, the heat sink structure 700 takes heat away from the packaged IC structure 250.

As power density requirements increase, hot spot thermal dissipation becomes one of the most critical issues. Hot spots are the hottest locations of a die, normally in CPU/GPU regions. As described herein, when the chip (e.g., hot spots of the die 200) heats up, the lid 506/die 200/package substrate 606 may warp, causing the TIM layer 504a between the lid 506 and the die 200 to delaminate, which in turn causes the lid 506 and TIM layer 504a interface to have poor contact causing air gaps and increased thermal resistance. The compression mechanism described herein eliminates defects caused by poor contacts of the lid 506 to the TIM layer 504a (e.g., prevent delamination issues caused by die 200 bending down and lid 506 bending up). The compression also reduces overall PCB and package warp to improve mechanical robustness. As described herein, by having a back plate 150 with elastic protrusion parts (e.g., curvature leaf spring arms, protrusion stubs, and/or spring units), there generates a pre-pressure force on the back side of the PCB 610 within a projected area of the die 200 (e.g., aimed at hot spots). This reduces the TIM delamination issues. In an embodiment, the elastic protrusion parts may include but are not limited to metallic materials such as aluminum (Al) and stainless steel (SUS).

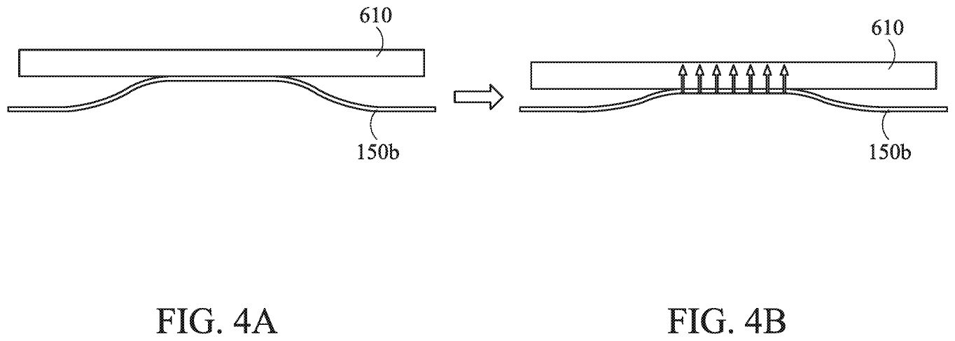

Referring now to the right figure of FIG. 3, the protrusion portion 150b may include a curvature leaf spring arm. The curvature spring leaf arm may be a flat spring with a middle curvature portion that compresses against the PCB 610 as shown by the upward arrows. The ends of the flat spring (flat portions) may be mounted onto the base portion 150a. FIGS. 4A-4B illustrate the mechanism of enhanced heat transfer using a leaf spring arm as part of a back plate 150 of an IC package assembly 100. FIG. 4A illustrates a leaf spring arm before compression. FIG. 4B illustrates the leaf spring arm after compression. For example, as the fasteners 702 are bolted and secured onto the back plate 150, the mechanical pressure applied by the fasteners 702 is absorbed by the leaf spring arm, thereby causing the leaf spring arm to depress and apply compression force to the PCB 610. Or more specifically, the curvature portion of the leaf spring arm is depressed, and the curvature portion is aligned with the projected area of the die 200, thereby transferring the applied force to the projected die area. The curvature leaf spring arm can be plate-shaped or disc-shaped from a top view. The pre-pressure force of the leaf spring arm may target hot spot areas of the die 200.

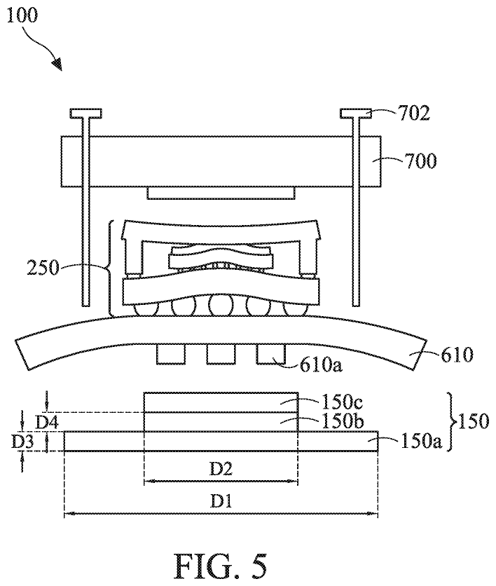

FIG. 5 illustrates an IC package assembly 100 having a back plate 150 with a single protrusion pad. In other words, the protrusion portion 150b is a single protrusion pad having a uniform lateral width (and/or length). In the case where the lateral width and the lateral length are the same, the protrusion portion 150b is a square protrusion pad. FIG. 5 resembles previous figures described above. As shown, the back plate 150 includes a base portion 150a, which may be a rigid base plate, and a single protrusion pad (i.e., the protrusion portion 150b) protruding from the base portion 150a. The base portion 150a spans a lateral width (and/or length) D1. In an embodiment, the lateral width (and/or length) D1 ranges between about 50 mm to about 200 mm. The single protrusion pad spans a lateral width (and/or length) D2. In an embodiment, the lateral width (and/or length) D2 ranges between about 40 mm to about 150 mm. As such, the lateral width (and/or length) D1 of the base portion 150a is greater than the lateral width (and/or length) D2 of the protrusion pad (i.e., the protrusion portion 150b). In other words, a lateral width of the protrusion portion 150b is smaller than a lateral width of the base portion 150a. In an embodiment, the ratio between D2 to D1 is in a range between about 0.5 to about 0.14. In an embodiment, the base portion 150a spans a height D3 ranging between about 0.5 mm to about 5 mm, and the protrusion portion 150b spans a height D4 ranging between about 0.5 mm to about 5 mm. In an embodiment, the ratio between D3 to D4 is in a range between about 0.5 to about 1.

Still referring to FIG. 5, note that the single protrusion pad 150b has a pad surface area, the packaged IC structure 250 has a package surface area, and the ratio between the pad surface area to the package surface area is in a range between about 0.8 to about 1.2. In other words, the lateral widths (and/or lengths) of the protrusion portion 150b and the packaged IC structure 250 may be similar so as to ensure proper vertical alignment between the protrusion portion 150b and the packaged IC structure 250. The lateral width (and/or length) of the packaged IC structure 250 may be a lateral width (and/or length) of the package substrate 606 or the lid 506. As shown, the single protrusion pad is vertically aligned with and directly below the packaged IC structure 250. In an embodiment, the single protrusion pad vertically overlaps the entire width of the die 200, which is smaller than the width of the packaged IC structure 250. As described previously, the vertical alignment between the protrusion portion 150b and the packaged IC structure 250 and the die 200 is to facilitate targeted compression at the die area for improved thermal contact. Even still, with the back plate configuration described herein, the PCB 610 may warp around 150 μm to around 500 um.

Still referring to FIG. 5, the back plate 150 may include an elastomer pad 150c as part of or separately disposed over a top surface of the protrusion portion 150b. The elastomer pad 150c may have the lateral dimension D2 but the present disclosure is not limited thereto. In any case, the elastomer pad 150c (if present) directly contacts and presses against the PCB 610. In the present embodiment, the elastomer pad 150c directly contacts and presses against the SMT components 610a. To avoid damaging the SMT components 610a, the elastomer pad 150c provides cushion to limit upward compression force and to mitigate board tensile effect. In some embodiments, the elastomer pad 150c is omitted. For example, the elastomer pad 150c is omitted if there are no SMT components 610a on a back side of the PCB 610 or if avoiding compression to the SMT components 610a is not critical.

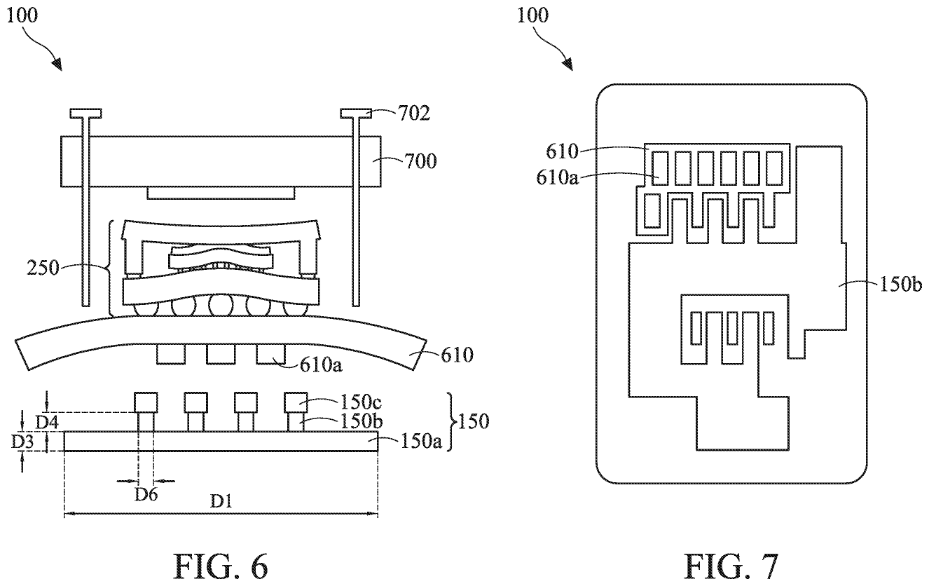

FIG. 6 illustrates an IC package assembly 100 having a back plate 150 with protrusion stubs. In other words, the protrusion portion 150b includes a plurality of protrusion stubs. In this embodiment, the back plate 150 still includes a base portion 150a, which may be a rigid base plate. The base portion 150a spans a lateral width (and/or length) D1 as described above with respect to FIG. 5. The back plate 150 further includes multiple protruding stubs protruding from the base portion 150a. The protruding stubs are distanced away from each other, and each of the protruding stubs spans a lateral width (and/or length) D6. A distance between edge protruding stubs may equal to the lateral width (and/or length) D2 as described above with respect to FIG. 5. In an embodiment, the lateral width (and/or length) D6 ranges between about 1 mm to about 10 mm. In an embodiment, the ratio between D6 to D1 is in a range between about 0.1 to about 0.5. In an embodiment, the base portion 150a spans a height D3 ranging between about 0.5 mm to about 5 mm, and the protrusion portion 150b spans a height D4 ranging between about 0.5 mm to about 5 mm. In an embodiment, the ratio between D3 to D4 is in a range between about 0.5 to about 1.

Still referring to FIG. 6, note that each of the protrusion stubs may include respective elastomer pads 150c as part of or separately disposed over respective top surfaces of the protrusion stubs. As shown, the protrusion stubs and the elastomer pads 150c may be staggered with the SMT components 610a when SMT components 610a are easily damaged (even when elastomer pads 150c are present). In this case, the protrusion stubs avoid touching the SMT components 610a and directly press against the back side surface of the PCB 610. The lateral dimensions of the elastomer pads 150c can be larger than, smaller than, or equal to the lateral dimensions of the protrusion stubs (e.g., D6).

FIG. 7 illustrates an IC package assembly 100 having a protrusion stub of irregular bump size. In other words, the protrusion portion 150b is a single stub having irregular lateral widths and lengths. FIG. 7 illustrates combined elements of the embodiments shown in FIG. 5 and FIG. 7. Like in FIG. 5, the protrusion stub in FIG. 7 is a single continuous block protruding from the base portion 150a, and like in FIG. 6, the protrusion stub avoids touching the SMT components 610a. As such, the protrusion stub may be a block of irregular bump size as long as it fills areas without SMT components 610a (e.g., landing on the PCB 610 and between the SMT components 610a).

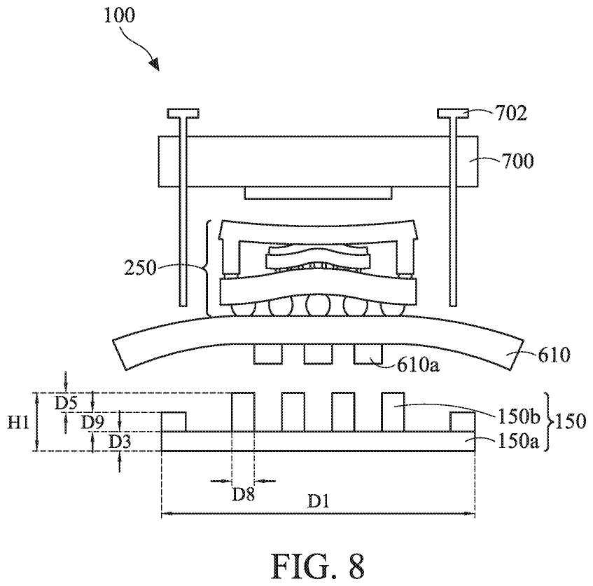

FIG. 8 illustrates an IC package assembly 100 having a back plate 150 with spring units. In other words, the protrusion portion 150b includes a plurality of spring units (e.g., coil springs). In this embodiment, the back plate 150 still includes a base portion 150a, which may be a rigid base plate. However, the base portion 150a may include plate walls to form a groove where the plurality of spring units are disposed. The base portion 150a spans a lateral width (and/or length) D1 as described above with respect to FIG. 5. The back plate 150 further includes multiple spring units protruding from the base portion 150a. The spring units may include compression springs, conical springs, torsion springs, spiral springs, Belleville springs, or other types of mechanical springs. The spring units are distanced away from each other, and each of the spring units spans a lateral width (and/or length) D8. A distance between edge spring units may equal to the lateral width (and/or length) D2 as described above with respect to FIG. 5. In an embodiment, the lateral width (and/or length) D8 ranges between about 3 mm to about 10 mm. In an embodiment, the ratio between D8 to D1 is in a range between about 0.01 to about 0.3. In an embodiment, the groove portion of the base portion 150a spans a height D3 ranging between about 0.5 mm to about 5 mm, and the plate walls of the base portion 150a spans a height D9 ranging between about 0.2 mm to about 5 mm. In an embodiment, the spring units span a height D5 beyond the plate wall top surface before fasteners 702 are secured. The height D5 may range between about 5 mm to about 20 mm. After fasteners 702 are secured, the spring units span the height D9 (e.g., height reduced due to compression of the spring units). As a result, the backside pressure may be precisely controlled. The height H1 from a bottom surface of the base portion 150a to a top surface of the spring units (before compression) may range between about 10 mm to about 30 mm. The ratio of D5 to H1 may range between about 0.3 to about 0.6. In some embodiments, the spring units may have different elastic modulus. For example, spring units closer to the center of the die 200 may have a larger elastic coefficient.

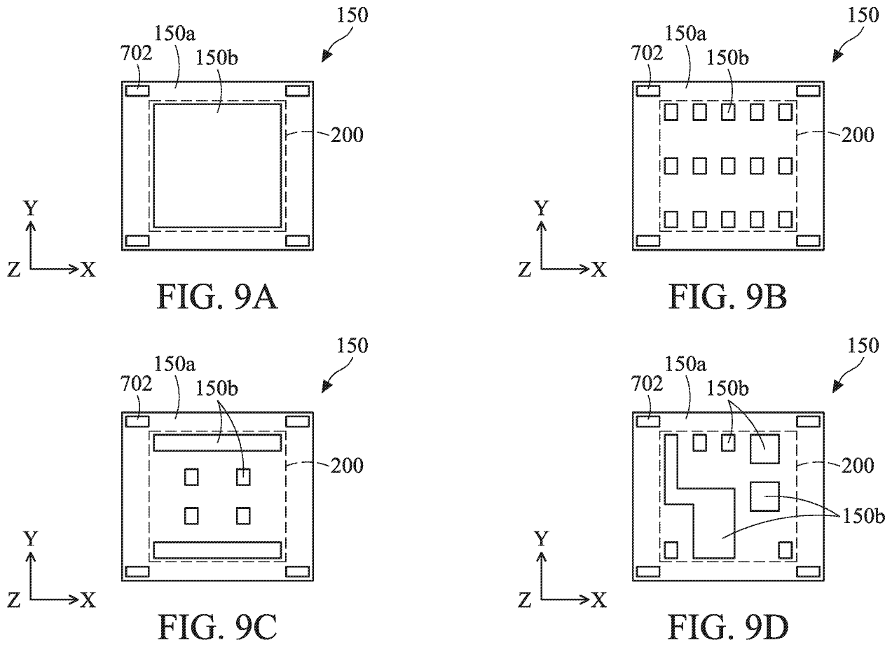

FIGS. 9A-9D illustrate back plates 150 with various types of square and rectangular protrusion features. In each of FIGS. 9A-9D, the various square and rectangular protrusion features are represented by the protrusion portion 150b, which protrude from the base portion 150a. As shown, in each of FIGS. 9A-9D, the base portion 150a has a greater width and length along the x and y direction than the protrusion portion 150b. Further, in each of FIG. 9A-9D, the fasteners 702 are bolted onto the base portion 150a. For example, fasteners 702 are bolted at the four corners of the back plate 150. In each of FIGS. 9A-9D, the protrusion portion 150b (or at least a portion thereof) overlaps with the die 200 (see dashed box) in the z direction. In this way, the protrusion portion 150b applies compression to the targeted die regions.

Now referring to FIG. 9A, the protrusion portion 150b may be a single protrusion pad that substantially mirrors the x and y dimensions of the die 200. The single protrusion pad is disposed directly below the area of the die 200. As shown, the single protrusion pad may be squared-shaped having uniform dimensions in the x and y direction. In embodiments where the die 200 is rectangular-shaped, the single protrusion pad may be rectangular-shaped to mirror the die 200. The single protrusion pad may correspond to the protrusion pad described with respect to FIG. 5.

Now referring to FIG. 9B, the protrusion portion 150b may include multiple protrusion stubs uniformly spread out and disposed directly below the area of the die 200. As shown, the protrusion stubs may be squared-shaped having uniform dimensions in the x and y direction (e.g., D6 in FIG. 6). Each of the protrusion stubs may be spaced away from each other in the x and y direction. In an embodiment, the protrusion stubs may correspond to the protrusion stubs described with respect to FIG. 6. For example, the SMT components 610a are staggered with the protrusion stubs so that the SMT components 610a are not directly pressed against.

Now referring to FIG. 9C, the protrusion portion 150b may include multiple protrusion stubs oriented in a different configuration. For example, some of the protrusion stubs are rectangular stubs that extend lengthwise along a perimeter of the die 200. The extending rectangular stubs may provide structural and uniform stress distribution while other stubs are targeted to specific areas (e.g., stubs in the middle target or surround hot spot areas).

Now referring to FIG. 9D, the protrusion portion 150b may include multiple protrusion stubs oriented in yet a different configuration. For example, the protrusion stubs are of different rectangular sizes and shapes, and they are distributed nonuniformly below the die 200. Some of the protrusion stubs may join together to form a protrusion of irregular bump size (like the one shown in FIG. 7). Some of the protrusion stubs may be distinct protrusion stubs spaced away from other protrusion stubs.

The protruding portions 150b in FIGS. 9B-9D have been described as corresponding to protrusion stubs. In an embodiment, some of the protruding portions 150b may correspond to spring units (like ones shown in FIG. 8). The present disclosure contemplates that the protrusion portion 150b for FIGS. 9B-9D may include all protrusion stubs, all spring units, or a combination of protrusion stubs and spring units.

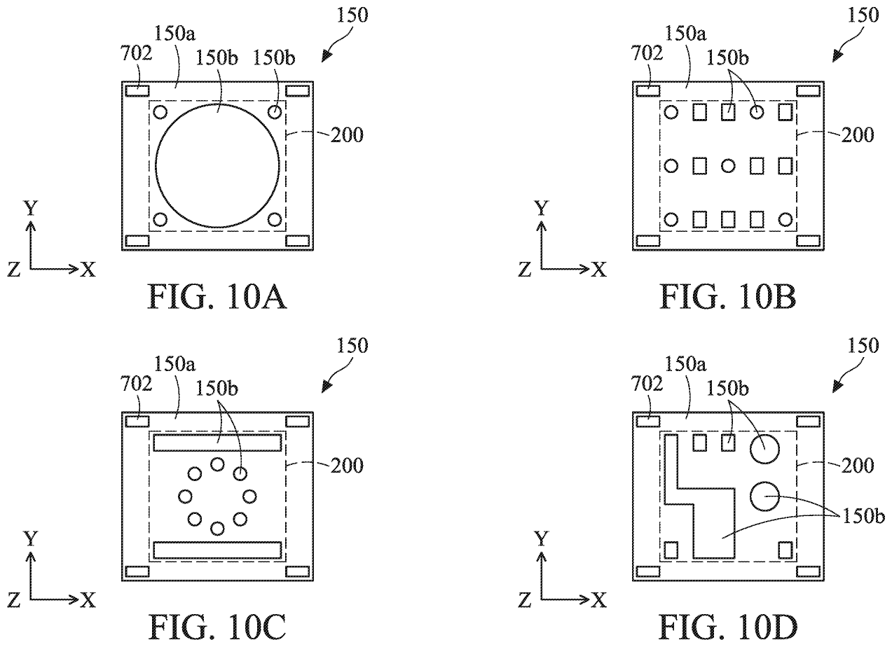

FIGS. 10A-10D illustrate back plates 150 with various types of circular, square, and rectangular protrusion features. In each of FIGS. 10A-10D, the various circular, square, and rectangular protrusion features are represented by the protrusion portion 150b, which protrude from the base portion 150a. As shown, in each of FIGS. 10A-10D, the base portion 150a has a greater width and length along the x and y direction than the protrusion portion 150b. Further, in each of FIG. 10A-10D, the fasteners 702 are bolted onto the base portion 150a. For example, fasteners 702 are bolted at the four corners of the back plate 150. In each of FIGS. 10A-10D, the protrusion portion 150b (or at least a portion thereof) overlaps with the die 200 (see dashed box) in the z direction. In this way, the protrusion portion 150b applies compression to the targeted die regions.

Now referring to FIG. 10A, the protrusion portion 150b may include a large circular protrusion pad that substantially mirrors the x and y dimensions of the die 200. In an embodiment, the protrusion portion 150b further includes smaller circular protrusion stubs vertically aligned with corner areas of the die 200. The smaller circular protrusion stubs may provide structural and uniform stress distribution to the die 200 in cases where the stress applied to the middle area is too great. As shown, each of the large circular protrusion pad and the corner circular protrusion stubs are disposed directly below the area of the die 200.

Now referring to FIG. 10B, the protrusion portion 150b may include multiple protrusion stubs uniformly spread out and disposed directly below the area of the die 200. As shown, the protrusion stubs may be squared-shaped and/or circular-shaped having uniform dimensions in the x and y direction. Each of the protrusion stubs may be spaced away from each other in the x and y direction. In an embodiment, the protrusion stubs may correspond to the protrusion stubs described with respect to FIG. 6. For example, the SMT components 610a are staggered with the protrusion stubs so that the SMT components 610a are not directly pressed against.

Now referring to FIG. 10C, the protrusion portion 150b may include multiple protrusion stubs oriented in a different configuration. For example, some of the protrusion stubs are rectangular stubs that extend lengthwise along a perimeter of the die 200. The extending rectangular stubs may provide structural and uniform stress distribution while other stubs are targeted to specific areas (e.g., stubs in the middle target or surround hot spot areas). In the embodiment shown, the middle stubs may be circular stubs surrounding a specific area, where the surrounded area include SMT components 610a.

Now referring to FIG. 10D, the protrusion portion 150b may include multiple protrusion stubs oriented in yet a different configuration. For example, the protrusion stubs are of different rectangular and circular sizes and shapes, and they are distributed nonuniformly below the die 200. Some of the protrusion stubs may join together to form a protrusion of irregular bump size (like the one shown in FIG. 7). Some of the protrusion stubs may be distinct protrusion stubs spaced away from other protrusion stubs.

The protruding portions 150b in FIGS. 10A-10D have been described as corresponding to protrusion stubs. In an embodiment, some of the protruding portions 150b may correspond to spring units (like ones shown in FIG. 8). The present disclosure contemplates that the protrusion portion 150b for FIGS. 10A-10D may include all protrusion stubs, all spring units, or a combination of protrusion stubs and spring units.

Although not limiting, the present disclosure offers advantages for IC package assemblies. One example advantage is to incorporate back plates having protrusion features for improved thermal contact. The protrusion features provide compression against a projected area of a die to avoid delamination between the die and a TIM layer. Another example advantage is targeting the protrusion features to hot spot areas of the IC package. Another example advantage is avoiding pressing against SMT components when applying compression to the back side of a PCB. Another example advantage is to incorporate elastomer pads to cushion pressure impact of the protrusion features on the back side of the PCB. Another example advantage is having various types of protrusion features (pads, stubs, springs, etc.) according to design needs.

One aspect of the present disclosure pertains to an integrated circuit (IC) package assembly. The IC package assembly includes a printed circuit board (PCB); a packaged IC structure mounted on a top surface of the PCB; a heat sink structure disposed over the packaged IC structure; and a back plate secured on a bottom surface of the PCB. The back plate includes a base portion and a protruding portion. The protrusion portion protrudes from the base portion and a portion of the PCB is below the packaged IC structure. A lateral width of the protrusion portion is smaller than a lateral width of the base portion.

In an embodiment, the packaged IC structure includes: a die; a thermal interface material (TIM) layer disposed on a top surface the die; and a metal lid disposed on a top surface of the TIM layer. The protrusion portion is configured to generate a pre-pressure force onto a back side of the PCB, and the pre-pressure force is transferred to a projected area of the die.

In a further embodiment, the pre-pressure force squeezes the die against the metal lid such that the TIM layer is substantially free of air gaps and delamination.

In an embodiment, the IC package assembly further includes fasteners that secure the heat sink structure to the back plate, where the fasteners apply a mechanical pressure onto the packaged IC structure by being bolted onto a top surface of the back plate. In a further embodiment, the applied mechanical pressure is about equal to 10 to 50 PSI.

In an embodiment, the IC package assembly further includes an elastomer pad that interface between the protrusion portion of the back plate and the bottom surface of the PCB.

In an embodiment, the protrusion portion of the back plate is a leaf spring arm, a plurality of stubs, or a plurality of springs.

In an embodiment, the heat sink structure includes cooling fans, cooling plates, or combinations thereof.

In an embodiment, the PCB includes surface mount (SMT) components on a back side of the PCB, and the protrusion portion of the back plate presses against the SMT components.

In an embodiment, the PCB includes surface mount (SMT) components on a back side of the PCB, and the protrusion portion of the back plate avoids pressing against the SMT components.

Another aspect of the present disclosure pertains to an integrated circuit (IC) package assembly. The IC package assembly includes a package substrate; a die over the package substrate; a first thermal interface material (TIM) layer over the die; a metal lid over the TIM layer; a second TIM layer over the metal lid; a heat sink structure over the second TIM layer; and a back plate under the package substrate. The back plate includes a base portion, a protruding portion, and an elastomer pad interposed between the protrusion portion and the package substrate. The protrusion portion protrudes from the base portion. The protrusion portion is below the die.

In an embodiment, the IC package assembly further includes fasteners that secure the heat sink structure to the back plate. The fasteners are configured to apply a force against a top surface of the metal lid.

In an embodiment, the base portion spans a first width, the protrusion portion spans a second width, and a ratio of the second width to the first width ranges between about 0.8 to about 1.2.

In an embodiment, the protrusion portion vertically overlaps an entire width of the die.

In an embodiment, the protrusion portion includes a plurality protrusion features, and each protrusion feature is distanced away from each other.

Another aspect of the present disclosure pertains to an integrated circuit (IC) package assembly. The IC package assembly includes a package substrate; a die over the package substrate; surface mount (SMT) components mounted on a backside of the package substrate; and a back plate under the package substrate. The back plate includes a base portion and a protruding portion. The protrusion portion protrudes from the base portion and presses against a back side of the package substrate. The protrusion portion is below the die and presses against the backside of the package substrate without contacting the SMT components.

In an embodiment, the protrusion portion lands between the SMT components.

In an embodiment, the protrusion portion includes a plurality of stubs, or a plurality of springs.

In an embodiment, the IC package assembly further includes elastomer pads disposed on a top surface of the protruding portion, and the elastomer pads directly contact the backside of the package substrate.

In an embodiment, the IC package assembly further includes a thermal interface material (TIM) layer over the die; a metal lid over the TIM layer; a heat sink structure over the metal lid; and fasteners that secure the heat sink structure to the back plate, wherein the fasteners apply a force against a top surface of the metal lid.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) package assembly, comprising:
a printed circuit board (PCB);
a packaged IC structure mounted on a top surface of the PCB;
a heat sink structure disposed over the packaged IC structure; and
a back plate secured on a bottom surface of the PCB, wherein the back plate includes a base portion and a protruding portion, wherein the protrusion portion protrudes from the base portion and a portion of the PCB is below the packaged IC structure,
wherein a lateral width of the protrusion portion is smaller than a lateral width of the base portion.

2. The IC package assembly of claim 1, wherein the packaged IC structure includes:
a die;
a thermal interface material (TIM) layer disposed on a top surface the die; and
a metal lid disposed on a top surface of the TIM layer, wherein the protrusion portion is configured to generate a pre-pressure force onto a back side of the PCB, and the pre-pressure force is transferred to a projected area of the die.

3. The IC package assembly of claim 2, wherein the pre-pressure force squeezes the die against the metal lid such that the TIM layer is substantially free of air gaps and delamination.

4. The IC package assembly of claim 1, further comprising:
fasteners that secure the heat sink structure to the back plate, wherein the fasteners apply a mechanical pressure onto the packaged IC structure by being bolted onto a top surface of the back plate.

5. The IC package assembly of claim 4, wherein the applied mechanical pressure is about equal to 10 to 50 PSI.

6. The IC package assembly of claim 1, further comprising:
an elastomer pad that interface between the protrusion portion of the back plate and the bottom surface of the PCB.

7. The IC package assembly of claim 1, wherein the protrusion portion of the back plate is a leaf spring arm, a plurality of stubs, or a plurality of springs.

8. The IC package assembly of claim 1, wherein the heat sink structure includes cooling fans, cooling plates, or combinations thereof.

9. The IC package assembly of claim 1, wherein the PCB includes surface mount (SMT) components on a back side of the PCB, and the protrusion portion of the back plate presses against the SMT components.

10. The IC package assembly of claim 1, wherein the PCB includes surface mount (SMT) components on a back side of the PCB, and the protrusion portion of the back plate avoids pressing against the SMT components.

11. An integrated circuit (IC) package assembly, comprising:
a package substrate;
a die over the package substrate;
a first thermal interface material (TIM) layer over the die;
a metal lid over the TIM layer;
a second TIM layer over the metal lid;
a heat sink structure over the second TIM layer; and
a back plate under the package substrate, wherein the back plate includes a base portion, a protruding portion, and an elastomer pad interposed between the protrusion portion and the package substrate, wherein the protrusion portion protrudes from the base portion, wherein the protrusion portion is below the die.

12. The IC package assembly of claim 11, further comprising:
fasteners that secure the heat sink structure to the back plate, wherein the fasteners are configured to apply a force against a top surface of the metal lid.

13. The IC package assembly of claim 11, wherein the base portion spans a first width, the protrusion portion spans a second width, and a ratio of the second width to the first width ranges between about 0.8 to about 1.2.

14. The IC package assembly of claim 13, wherein the protrusion portion vertically overlaps an entire width of the die.

15. The IC package assembly of claim 13, wherein the protrusion portion includes a plurality protrusion features, and each protrusion feature is distanced away from each other.

16. An integrated circuit (IC) package assembly, comprising:
a package substrate;
a die over the package substrate;
surface mount (SMT) components mounted on a backside of the package substrate; and
a back plate under the package substrate, wherein the back plate includes a base portion and a protruding portion, wherein the protrusion portion protrudes from the base portion and presses against a back side of the package substrate, wherein the protrusion portion is below the die and presses against the backside of the package substrate without contacting the SMT components.

17. The IC package assembly of claim 16, wherein the protrusion portion lands between the SMT components.

18. The IC package assembly of claim 16, wherein the protrusion portion includes a plurality of stubs, or a plurality of springs.

19. The IC package assembly of claim 16, further comprising:
elastomer pads disposed on a top surface of the protruding portion, and the elastomer pads directly contact the backside of the package substrate.

20. The IC package assembly of claim 16, further comprising:
a thermal interface material (TIM) layer over the die;
a metal lid over the TIM layer;
a heat sink structure over the metal lid; and
fasteners that secure the heat sink structure to the back plate, wherein the fasteners apply a force against a top surface of the metal lid.
